(19) United States
(12) Patent Application Publication
(10) Pub. No.: US 2006/0236179 A1
(43) Pub. Date: Oct. 19, 2006

(54) Delay test method for large-scale integrated circuits

(76) Inventor: Masanori Ushikubo, Yamanashi (JP)

Correspondence Address: RABIN & Berdo, PC, 1101 14TH STREET, NW, SUITE 500, WASHINGTON, DC, 20005, US

(21) Appl. No.: 11/384,437

(22) Filed: Mar. 21, 2006

(30) Foreign Application Priority Data
Apr. 14, 2005 (JP) 2005-116468

(51) Int. Cl. G01R 31/28

(52) U.S. Cl. 714/726

(57) ABSTRACT

The propagation delay of a combinatorial circuit in a large-scale integrated circuit is tested by carrying out two scan tests. Both scan tests generate the same input signal transitions to the combinatorial circuit. One scan test scans the outputs of the combinatorial circuit after the transitions propagate through the combinatorial circuit, using separate launch and capture clock pulses. The other test scans the outputs of the combinatorial circuit before the transitions propagate through the combinatorial circuit, using the same clock pulse for both launch and capture. Use of both tests ensures that propagation delay faults are not masked by large capture clock delays.

### BACKGROUND OF THE INVENTION

1. Field of the Invention

The present invention relates to a method of testing a large-scale integrated (LSI) circuit with a built-in scan test function, to detect delay faults.

2. Description of the Related Art

Part of an LSI circuit with a built-in scan test function is illustrated schematically in FIG. 1. Combinatorial circuits 1A and 1B are linked through scan flip-flops (S-FF) 2B₁, 2B₂, . . . , 2Bₘ, which are interconnected to form a scan chain 2B. Each scan flip-flop includes a selector 7 controlled by a scan enable signal SE to select an input signal and a flip-flop 8 that latches the selected signal in synchronization with a clock signal CKB and outputs the latched signal.

Signals output in parallel from combinatorial circuit 1A are supplied to the first inputs of the selectors 7 in the scan flip-flops 2B₁, 2B₂, . . . , 2Bₘ, and the signals output from the flip-flops 8 are supplied in parallel to the input side of combinatorial circuit 1B. The output of the flip-flop 8 in each of the first m−1 scan flip-flops 2B₁, 2B₂, . . . , 2Bₘ is also connected to the second input of the selector 7 in the next scan flip-flop 2B₂, 2B₃, . . . , 2Bₘ. The second input of the selector 7 in the first scan flip-flop 2B₁ in the chain is connected to a scan input terminal 3B, and the output of the flip-flop 8 in the last scan flip-flop 2Bₘ in the chain is connected to a scan output terminal 4B.

Signals from another chain 2A of scan flip-flops 2A₁, 2A₂, . . . , 2Aₖ are supplied in parallel to the input side of combinatorial circuit 1A. The second input of the selector 7 in scan flip-flop 2A₁ is connected to a scan input terminal 3A; the output of the flip-flop 8 in scan flip-flop 2Aₖ is connected to a scan output terminal 4A.

A third chain 2C of scan flip-flops 2C₁, 2C₂, . . . , 2Cₙ is connected to the output side of combinatorial circuit 1B. The second input of the selector 7 in scan flip-flop 2C₁ is connected to a scan input terminal 3C; the output of the flip-flop 8 in scan flip-flop 2Cₙ is connected to a scan output terminal 4C.

A clock signal CLK is supplied from a clock terminal 5 to the clock input terminal of the flip-flop 8 in each scan flip-flop via a clock distribution circuit or clock tree. The scan enable signal SE is supplied to the control terminal of the selector 7 in each scan flip-flop from a scan enable terminal 6.

A conventional delay test of combinatorial circuit 1B in FIG. 1 is conducted as illustrated by the signal waveform diagram in FIG. 2. It is assumed that combinatorial circuits 1A and 1B input and output four signals each. The delay being tested is the propagation delay D from the input of test data to the input side of combinatorial circuit 1B to the output of signals indicating the results of logic operations on the test data from the output side of combinatorial circuit 1B. The clock signal CLK supplied from the clock terminal 5 propagates as a clock signal CKB with a delay α to scan chain 2B and as a clock signal CKC with a delay β to scan chain 2C.

First, the scan enable signal SE is set to the high logic level, switching the selectors 7 of all scan flip-flops to the second input side. Scan flip-flops 2A₁ to 2A₄ thereby form a shift register extending from scan input terminal 3A to scan output terminal 4A, the signals output from the scan flip-flops 2A₁ to 2A₄ also being supplied in parallel to combinatorial circuit 1A. Similarly, scan flip-flops 2B₁ to 2B₄ form a shift register extending from scan input terminal 3B to scan output terminal 4B, the signals output from scan flip-flops 2B₁ to 2B₄ also being supplied in parallel to combinatorial circuit 1B.

At time t1 in FIG. 2, the scan input signals SIA and SIB supplied to scan input terminals 3A and 3B are set according to test data TDA and TDB to signal levels ‘a4’and ‘b4’ (where ‘a4’and ‘b4’ are either the high or low logic level) and a clock pulse is supplied to the clock terminal 5. After propagation delays in the clock distribution circuitry, scan flip-flops 2A₁ and 2B₁ latch the data ‘4a’ and ‘4b’.

Next, at times t2, t3, and t4, scan input signals SIA (‘a3’, ‘a2’, ‘a1’) are supplied from the scan input terminal 3A one by one and shifted into scan chain 2A in synchronization with the clock signal CLK. Scan input signals SIB (‘b3’, ‘b2’, ‘b1’) are similarly shifted from scan input terminal 3B into scan chain 2B. After the above scan shift operations, test data TDA (‘a1’, ‘a2’, ‘a3’, ‘a4’) are held in scan flip-flops 2A₁ to 2A₄ and supplied in parallel to combinatorial circuit 1A, while test data TDB are held in scan flip-flops 2B₁ to 2B₄ and supplied in parallel to combinatorial circuit 1B. Combinatorial circuit 1A performs logic operations on test data TDA and, after a certain delay, outputs resultant signal data RDA in parallel as an input test pattern. In the meantime, combinatorial circuit 1B performs logic operations on test data TDB and, after a certain delay, outputs resultant signal data RDB1 in parallel.

At time t5, the scan enable signal SE at terminal 6 is driven low, switching the selectors 7 of all scan flip-flops to the first input side. The signals output from combinatorial circuit 1A are now supplied to scan chain 2B, but the data latched in scan flip-flops 2B₁ to 2B₄ do not immediately change, because no clock pulse is supplied to the clock terminal 5.

At time t6, a launch clock pulse is supplied from the clock terminal 5, reaching scan chain 2B as clock signal CKB with a delay α. The signal data RDA output from combinatorial circuit 1A and received by scan flip-flops 2B₁ to 2B₄ are supplied almost simultaneously to combinatorial circuit 1B. (As the circuits distributing the clock signals to scan flip-flop 2B₁ to 2B₄ are not quite identical, these flip-flops do not operate with perfect simultaneity.) Combinatorial circuit 1B now performs logic operations on the newly supplied signal data RDA and, after a concomitant delay D, outputs the results RDB2 to the first inputs of the selectors 7 in scan flip-flops 2C₁ to 2C₄. During this delay D, the signals output from combinatorial circuit 1B switch from their old values to their new values.

After a delay T from time t6, a capture clock pulse is supplied from the clock terminal 5 at time t7, reaching scan chain 2C as clock signal CKC with a delay β. Scan flip-flops 2C₁ to 2C₄ now latch the resultant signal data RDB2 from combinatorial circuit 1B. The scan output signal SOC output from scan output terminal 4C is ‘c4’.

At time t8, the scan enable signal SE returns to the high logic level and the selectors 7 of all scan flip-flop are switched to the second input side to resume scan shift operations.

The remaining data (‘c3’, ‘c2’, ‘c1’) captured in scan flip-flops 2C₁ to 2C₃ are then shifted one by one into scan flip-flop 2C₄ in synchronization with clock signal CKC and output serially as scan output signal SOC from scan output terminal 4C at times t9 to t11 (with a delay of β in each case).

The propagation delay D of the logic operations performed in combinatorial circuit 1B can therefore be tested by checking the scan output signal SOC following times t7, t9, t10, and t11. If the scan output signal SOC matches the values (the output test pattern) expected to be obtained from the input data RDA by the logic operations performed in combinatorial circuit 1B, it can be concluded that the following inequality (1) is satisfied.
α+D<β+T (1)

When the scan output signal SOC does not match the expected values, it can be concluded that the above inequality is not satisfied. This indicates that the delay D being tested has been prolonged for some reason, such as a defect introduced in the manufacturing process.

A delay test of the LSI circuit in FIG. 1 is carried out using the equipment illustrated in FIG. 3. First, logic circuit information describing the combinatorial circuits of the LSI circuit to be tested is supplied to a test pattern generating device 10 (for example, a computer with a program for generating test pattern data) that can generate test patterns for a delay test, and the relevant input and output scan segments are specified. In this example, the circuit to be tested is combinatorial circuit 1B, the relevant input scan segments are the scan chains 2A and 2B on the input sides of combinatorial circuits 1A and 1B, and the relevant output scan segment is the scan chain 2C on the output side of combinatorial circuit 1B.

The test pattern generating device 10 then generates test pattern data indicating the transitions over time of the signals CLK, SE, SIA, SIB, and SOC at terminals 5, 6, 3A, 3B, and 4C in the LSI circuit under test. The launch-to-capture delay T in the test pattern data is selected so that the above inequality (1) will be satisfied when the propagation delay D of combinatorial circuit 1B is within tolerance, and will not be satisfied when the propagation delay D is over tolerance.

Next, the resultant test pattern data are read into the scan test device 20. The scan test device 20 has a random-access memory (RAM) 22 in which the timings of the test pattern data are mapped onto different addresses. The status (‘1’ or ‘0’) of signals CLK, SE, SIA, and SIB and the expected status of signal SOC at each timing are stored at the corresponding address. The scan test device 20 also comprises a clock generator or oscillator (OSC) 24 that generates a read clock signal CK, an address counter 26 that counts the clock signal CK to generate a memory address signal ADR, and a comparator (CMP) 28. Data read out one by one from the memory 22 according to the address signal ADR are supplied as signals CLK, SE, SIA, SIB to the corresponding terminals 5, 6, 3A and 3B of the LSI circuit under test 30.

The expected SOC signal data read out from the memory 22 are supplied to one of the input terminals of the comparator and compared with the scan output signal SOC obtained from scan output terminal 4C of the circuit under test 30 (the scan output signal SOC is supplied to the other terminal of the comparator). The result of the comparison is output to indicate the test result.

The conventional procedure by which the test equipment in FIG. 3 is used to carry out a delay test of an LSI circuit 30 is shown by the flowchart in FIG. 4.

In step S1 in FIG. 4, information specifying the circuit configuration of combinatorial circuits 1A, 1B and other combinatorial circuits in the LSI circuit is set in the test pattern generating device 10.

In step S2, the scan segments on the input and output sides of the combinatorial circuit to be tested are specified. This completes the setting of the test pattern generating device 10.

In step S3, the test pattern generating device 10 generates the input test pattern that will propagate from the scan flip-flops in the input scan segments to the scan flip-flops in the output scan segment.

In step S4, the test pattern generating device 10 generates the output test pattern expected to appear in the output scan segment after the signal transition propagates from the input scan segment to the output scan segment.

In step S5, a launch clock pulse and a capture clock pulse are incorporated into the input test pattern generated in step S3 and the output test pattern generated in step S2, to generate test pattern data for the delay test.

In step S6, the test pattern data for the delay test are set in the scan test device 20. In step S7, the delay test is executed by supplying test signals from the scan test device 20 to the LSI circuit under test at times controlled by the clock generator 24 and address counter 26.

In step S8, the expected SOC output values generated as test pattern data in advance are compared with the scan output signal SOC actually output from the LSI circuit under test. If the SOC test pattern data signal and the SOC scan output signal match, the circuit passes the delay test; otherwise, the circuit is rejected as defective.

Japanese Patent Application Publication No. 5-119122 describes a method of generating test patterns for scan circuits so as to shorten the test time.

A general problem encountered when delay tests are carried out as described above is that a capture clock propagation delay may mask combinatorial logic delay faults. It is possible to compensate for a moderate known capture clock delay β by shortening the launch-to-capture clock delay T, but this becomes impractical when β is very large, or is unknown. For example, if the capture clock delay β is so great that α+D<β, then the inequality (1) given above will be satisfied regardless of the launch-to-capture delay T. If the capture clock is greatly delayed, then the scan chain 2C that captures the result data will sometimes receive the expected signals even though the circuit under test has a delay fault, and defective circuits will be misjudged as normal.

### SUMMARY OF THE INVENTION

An object of the present invention is to provide an accurate method of conducting a delay test of a large-scale integrated circuit.

The invented method tests a large-scale integrated circuit including a combinatorial circuit and scan flip-flops. The scan flip-flops are interconnected to form an input scan segment for launching at least one signal into the combinatorial circuit and an output scan segment for capturing at least one signal output from the combinatorial circuit. The method includes:

specifying the configuration of the combinatorial circuit and the input and output scan segments;

generating an input test pattern for placement in the input scan segment to create predetermined input signal transition(s) for the combinatorial circuit;

generating a first output test pattern indicating the signal value(s) expected to appear in the output scan segment after the input signal transition(s) propagate through the combinatorial circuit;

generating a second output test pattern indicating the signal value(s) expected to appear in the output scan segment before the input signal transition(s) propagate through the combinatorial circuit;

generating a first delay test pattern incorporating the input test pattern and the first output test pattern;

generating a second delay test pattern incorporating the input test pattern and the second output test pattern;

conducting delay tests of the large-scale integrated circuit with both the first and second delay test patterns;

passing the large-scale integrated circuit as normal if it passes both delay tests, and rejecting the large-scale integrated circuit as defective if it fails either of the two delay tests.

The first delay test pattern tests the propagation delay of the combinatorial circuit. The second delay test pattern tests the delay of the clock signal used to capture the signal(s) output from the combinatorial circuit to the output scan segment. Use of both test patterns ensures that propagation delay faults will not be masked large clock delays.

### BRIEF DESCRIPTION OF THE DRAWINGS

In the attached drawings:

FIG. 1 is a schematic diagram of part of an LSI circuit having a scan test function;

FIG. 2 is a signal waveform diagram illustrating a conventional delay test of the LSI circuit in FIG. 1;

FIG. 3 illustrates an equipment configuration for generating and executing the delay test;

FIG. 4 is a flowchart illustrating a conventional method of generating and executing a delay test using the equipment configuration in FIG. 3;

FIGS. 5A and 5B are a flowchart illustrating a novel method of generating and executing a delay test using the equipment configuration in FIG. 3; and

FIG. 6 is a signal waveform diagram illustrating the novel delay test method.

### DETAILED DESCRIPTION OF THE INVENTION

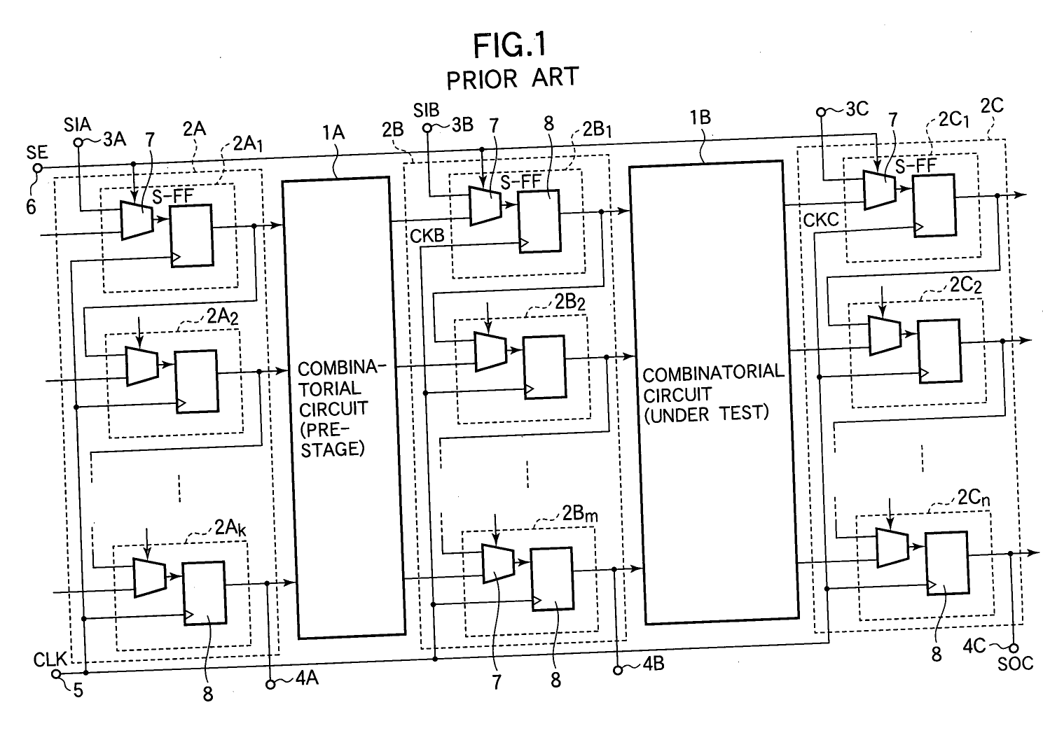

An embodiment of the invention will now be described with reference to FIGS. 1-3, 5A, 5B, and 6. The large-scale integrated circuit 30 in this embodiment includes a pre-stage combinatorial circuit 1A as well as the combinatorial circuit 1B to be tested. The scan flip-flops include a pre-stage scan segment (scan chain 2A) that launches signals into the pre-stage combinatorial circuit, an input scan segment (scan chain 2B) that latches signals output from the pre-stage combinatorial circuit and launches signals into the combinatorial circuit under test, and an output scan segment (scan chain 2C) that latches signals output from the combinatorial circuit under test. A predetermined transition of input signals to the combinatorial circuit under test is created by loading an input test pattern into the pre-stage scan segment and the input scan segment, waiting for the signals output by the pre-stage scan segment to propagate through the pre-stage combinatorial circuit, then applying a clock pulse that causes the input scan segment to latch the signals output by the pre-stage combinatorial circuit. These signals now begin to propagate through the combinatorial circuit under test.

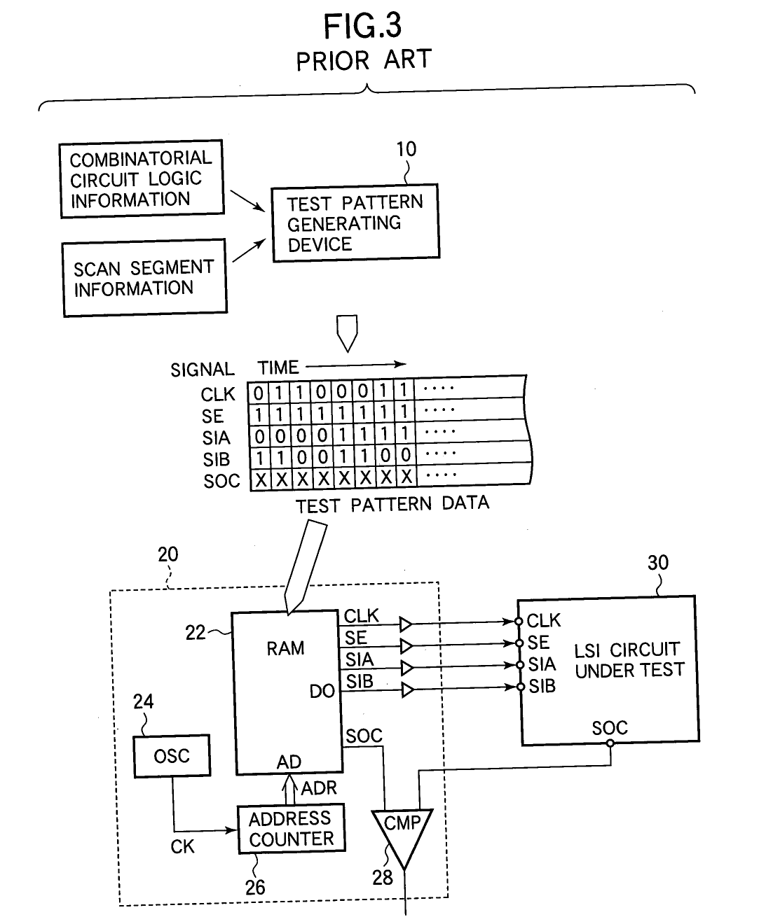

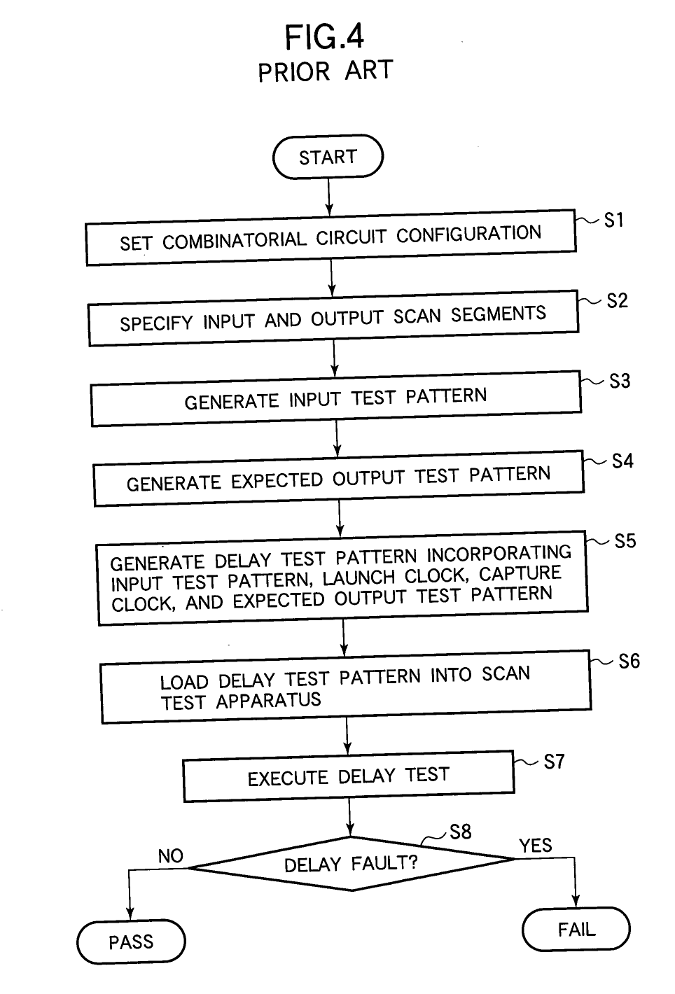

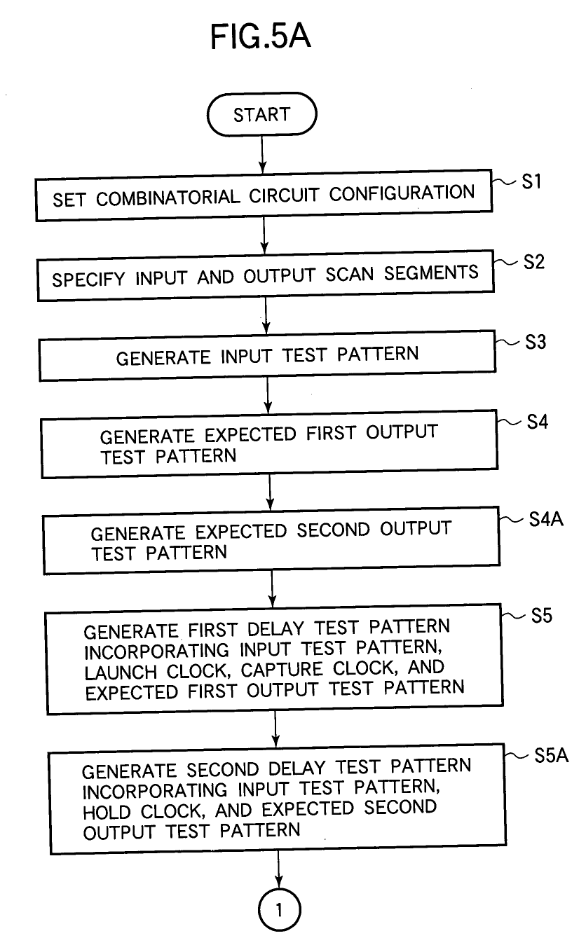

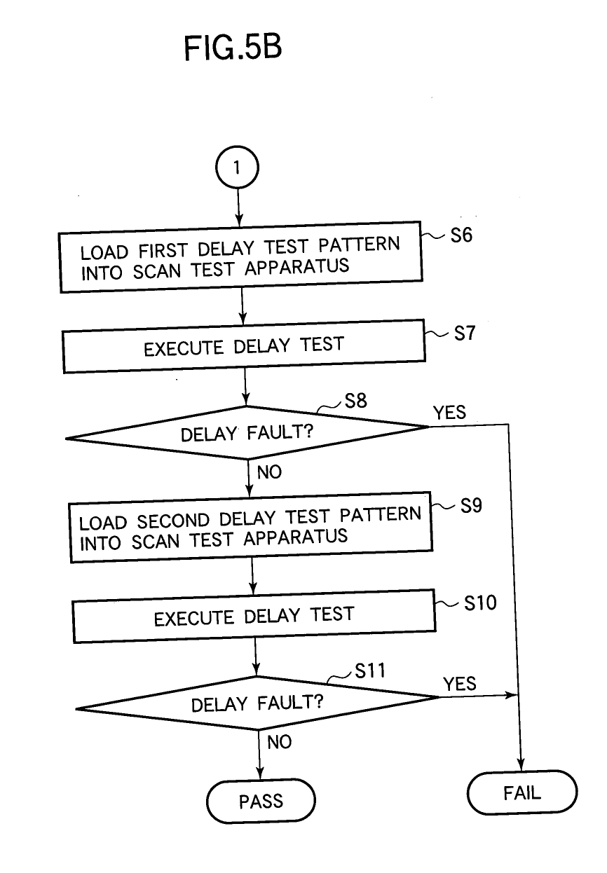

The test procedure is illustrated in the flowchart in FIGS. 5A and 5B. Identical reference characters are assigned to steps in which operations similar to the conventional operations in FIG. 4 are carried out. The test equipment configuration is as shown in FIG. 3.

In step S1 in FIG. 5A, information specifying the circuit configuration of combinatorial circuits 1A, 1B and other combinatorial circuits in the LSI circuit under test is set in the test pattern generating device 10 (see FIG. 3).

In step S2 in FIG. 5A, the scan segments on the input and output sides of the combinatorial circuit 1B to be tested are specified. In the present embodiment, the scan segments on the input side include the pre-stage scan chain 2A as well as the input scan chain 2B (see FIG. 1).

In step S3 in FIG. 5A, the test pattern generating device 10 generates the input test pattern for creating a signal transition that will propagate from the scan flip-flops in the input scan segment through combinatorial circuit 1B to the scan flip-flops in the output scan segment (scan chain 2C in FIG. 1).

In step S4 in FIG. 5A, the test pattern generating device 10 generates a first output test pattern expected to appear in the output scan segment after the signal transition propagates from the input scan segment to the output scan segment. These steps S1 to S4 are similar to the conventional test steps in FIG. 4.

Next in step S4A in FIG. 5A, the test pattern generating device 10 generates a second output test pattern expected to appear in the output scan segment 2C before the signal transition propagates from the input scan 2B segment to the output scan segment 2C.

In step S5, a clock pattern comprising a launch clock pulse and a capture clock pulse is incorporated into the input test pattern generated in step S3 and the first output test pattern generated in step S4 to generate first test pattern data for the delay test.

In step S5A, a clock pattern comprising a hold clock pulse is incorporated into the input test pattern generated in step S3 and the second output test pattern generated in step S2 to generate second test pattern data for the delay test. The hold clock pulse will be described later.

In step S6 in FIG. 5B, the first test pattern data generated in step S5 are set in the scan test device 20. In step S7, test signals are supplied from the scan test device 20 to the LSI circuit 30 under test to execute a first delay test.

In step S8, the scan output signal SOC output from the circuit 30 under test is compared with the first output test pattern. If the SOC signal data do not match the first output test pattern data, the circuit fails the test and is rejected as defective. If the signal data match the first output test pattern data, the test process proceeds to the next step S9.

In step S9, the second test pattern data generated in step S5A are set in the scan test device 20. In step S10, test signals are supplied from the scan test device 20 to the LSI circuit 30 under test to execute a second delay test.

In step S11, the scan output signal SOC output from the circuit 30 under test is compared with the second output test pattern. If the SOC signal data match the second output test pattern data, the circuit passes the test; otherwise, the circuit fails the test and is rejected as defective.

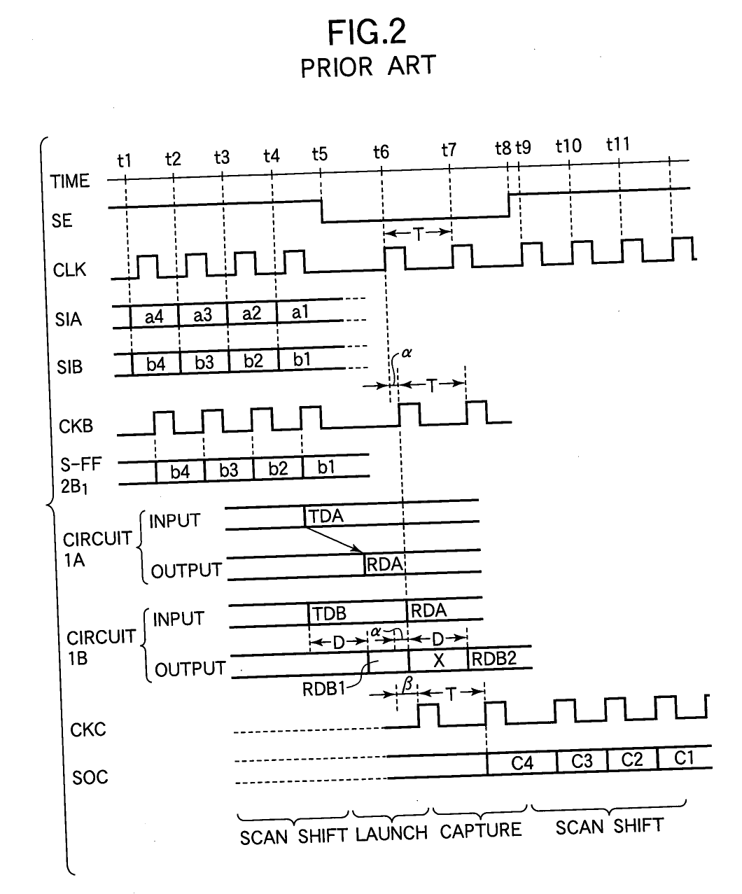

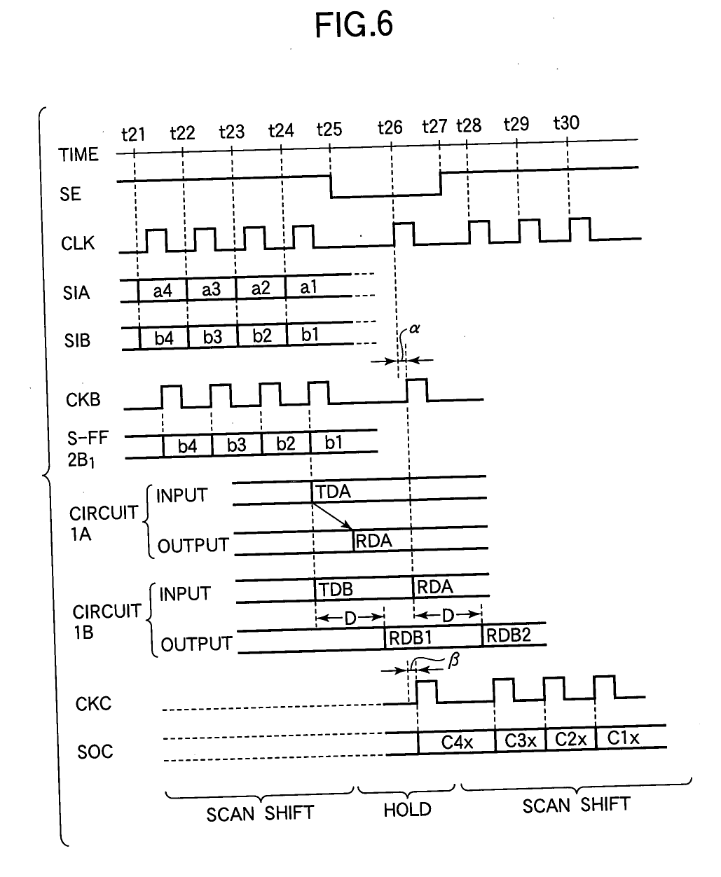

The first delay test carried out in step S7 in FIG. 5B is similar to the conventional delay test illustrated in FIG. 2. The second delay test carried out in step S10 in FIG. 5B is illustrated in FIG. 6, again under the assumption that the combinatorial circuits 1A and 1B have four input signals and four output signals each. As before, the clock signal CLK supplied to the clock terminal 5 propagates as clock signal CKB to the scan flip-flops in scan chain 2B with delay α, and as clock signal CKC to the scan flip-flops in scan chain 2C with delay β.

First, the scan enable signal SE is set to the high logic level, switching the selectors 7 of all scan flip-flops to the second input side. Scan flip-flops 2A₁ to 2A₄ form a shift register extending from scan input terminal 3A to scan output terminal 4A in FIG. 1, and their output signals are supplied in parallel to combinatorial circuit 1A. Similarly, scan flip-flops 2B₁ to 2B₄ form a shift register extending from scan input terminal 3B to scan output terminal 4B and their output signals are supplied in parallel to combinatorial circuit 1B.

At time t21 in FIG. 6, the scan input signals SIA and SIB supplied to scan input terminals 3A and 3B are set according to the predefined test data TDA and TDB, to signal levels ‘a4’and ‘b4’, and a clock pulse CLK is supplied to the clock terminal 5. After propagation delays in the clock distribution circuitry, scan flip-flops 2A₁ and 2B₁ latch the data ‘a4’and ‘b4’.

Next, at times t22, t23 and t24, scan input signals SIA (‘a3’, ‘a2’, ‘a1’) are supplied one by one from the scan input terminal 3A and shifted into scan chain 2A in synchronization with the clock signal CLK. Scan input signals SIB (‘b3’, ‘b2’, ‘b1’) are supplied one by one from scan input terminal 3B into scan chain 2B. After the above scan shift operation, test data TDA (‘a1’, ‘a2’, ‘a3’, ‘a4’) are latched in scan flip-flops 2A₁ to 2A₄, and supplied in parallel to combinatorial circuit 1A, while test data TDB are latched in scan flip-flops 2B₁ to 2B4 and supplied in parallel to combinatorial circuit 1B. Combinatorial circuit 1A performs logic operations on test data TDA, and after a certain delay, outputs the resultant signal data RDA in parallel as an input test pattern. In the meantime, combinatorial circuit 1B performs logic operations on test data TDB, and after a certain delay, outputs the resultant signal data RDB1 in parallel.

At time t25, the scan enable signal SE at terminal 6 is driven low, switching the selectors 7 of all scan flip-flops to the first input side. The signals output from combinatorial circuit 1A are now supplied to the input side of the flip-flops in scan chain 2B, but the data latched in scan flip-flops 2B₁ to 2B₄ do not immediately change, because no clock pulse is supplied to the clock terminal 5.

At time t26, a hold clock pulse is supplied from the clock terminal 5. This clock pulse reaches scan flip-flops 2B₁ to 2B₄ as clock signal CKB with a delay α, and reaches scan flip-flops 2C₁ to 2C₄ as clock signal CKC with a delay β. If delay β is less than delay α, as shown, then scan flip-flops 2C₁ to 2C₄ latch the signal data RDB1 output by combinatorial circuit 1B before it received the new input signal data RDA. Even if delay β is slightly greater than delay α, as in FIG. 2, scan flip-flops 2C₁ to 2C₄ will still latch signal data RDB1 (‘c1x’, ‘c2x’, ‘c3x’, ‘c4x’), provided the difference between delay α and delay β is less than the shortest time required for a signal transition to propagate through combinatorial circuit 1B. In other words, provided delay β does not too greatly exceed delay α, scan flip-flops 2C₁ to 2C₄ will latch signal data RDB1 and the scan output signal SOC output from scan flip-flop 2C₄ to scan output terminal SOC will be ‘c4x’.

At time t27, the scan enable signal SE is driven high, switching the selectors 7 of all scan flip-flops to the second input side to resume scan shift operations. In due time, the logic operations carried out on signal data RDA by combinatorial circuit 1B produce new output data RDB2, but the new output data RDB2 are ignored by the selectors 7 and are not latched in scan flip-flops 2C₁ to 2C₄.

The remaining data captured in scan flip-flops 2C₁ to 2C₃ in synchronization with the hold clock pulse at time t26 (+β) are now shifted into scan flip-flop 2C₄ one by one in synchronization with clock signal CKC, and output serially as scan output signal SOC from scan output terminal 4C at times t28 to t30 (in each case with a delay of β from the rise of clock signal CLK). The scan output signal SOC output from the scan output terminal 4C gives the data RDB1 output by combinatorial circuit 1B before the before the signal transition occurred.

The delay of clock signal CKB can therefore be tested by checking the scan output signal SOC following times t26, t28, t29, and t30. If the scan output signal SOC matches the values (the second output test pattern) expected to be obtained from test pattern TDB by the logic operations performed in combinatorial circuit 1B, it can be concluded that the passing result obtained in step S8 indicates that the propagation delay in combinatorial circuit 1B is within tolerance, and is not due to an excessive delay β of the clock signal CKC supplied to scan chain 2C.

If, for example, the delay β of clock signal CKC is greater than the sum of delays α and D (α+D<β), then the data latched by the scan flip-flops 2C₁ to 2C₄ in synchronization with the hold clock pulse will be the output signal RDB2 obtained after the signal transition propagates through combinatorial circuit 1B. Therefore, the data scanned out in step S10 will show the results of logic operations performed on input data RDA, not matching the second output test pattern, and the LSI circuit will be rejected as defective in step S11.

The invented test method can be described as performing both a conventional delay test with separate launch and capture clock pulses to check the propagation delay of a combinatorial circuit, and an additional test in which the launch and capture clock pulses are combined into a single hold clock pulse to check the propagation delay of the capture clock signal. This test procedure catches not only unacceptable logic propagation delays but also scan clock propagation delays that prevent the logic propagation delay from being tested accurately, thereby reducing the possibility of erroneous test results wherein a defective circuit is passed as non-defective.

In conventional test methods, the detectable delay time is limited by constraints on the launch-to-capture delay T imposed by the test equipment (for example T>5 ns), which may preclude testing under the condition α+D−β<T. The additional test conducted with the hold clock pulse in the present invention is free of such constraints.

It will be appreciated by those skilled in the art that many modifications can be made in the above embodiment. For example:

(1) the data launched into the combinatorial circuit under test may be input in parallel from external input terminals, instead of being scanned in; this modification is necessary when the combinatorial circuit under test is the first stage and there is no pre-stage combinatorial circuit on its input side;

(2) the LSI circuit may have a single scan chain, different segments of which function as the three scan chains shown in FIG. 1;

(3) the test equipment, including the scan test device and test pattern generating device, need not be configured as shown in FIG. 3;

(4) the order of steps in FIGS. 5A and 5B is not limited to the illustrated order. Any order can be used as long as the LSI circuit is passed as normal only if it passes tests using both the first and second test patterns. For example, steps S9-S11 can be carried out before steps S6-S8, the test in steps S6-S8 being conducted only if the test in steps S9-S11 passes.

Those skilled in the art will recognize that further variations are possible within the scope of the invention, which is defined in the appended claims.

What is claimed is:

1. A method of testing a large-scale integrated circuit including a combinatorial circuit and scan flip-flops to conduct a delay test of the combinatorial circuit, the scan flip-flops being interconnected to form an input scan segment for launching at least one signal into the combinatorial circuit and an output scan segment for capturing at least one signal output from the combinatorial circuit, the method comprising:
specifying configuration information describing the combinatorial circuit;
specifying the input scan segment and the output scan segment;
generating an input test pattern including at least one signal value placed in the input scan segment to create a predetermined transition of the at least one signal input to the combinatorial circuit;
generating a first output test pattern comprising at least one signal value expected to appear in the output scan segment after said transition propagates through the combinatorial circuit;
generating a second output test pattern comprising at least one signal value expected to appear in the output scan segment before said transition propagates through the combinatorial circuit;
generating a first delay test pattern incorporating the input test pattern and the first output test pattern;
generating a second delay test pattern incorporating the input test pattern and the second output test pattern;
conducting a first delay test of the large-scale integrated circuit with the first delay test pattern;
conducting a second delay test of the large-scale integrated circuit with the second delay test pattern;
passing the large-scale integrated circuit as normal if the large-scale integrated circuit passes both the first and second delay tests; and
rejecting the large-scale integrated circuit as defective if the large-scale integrated circuit fails either the first delay test or the second delay test.

2. The method of claim 1, wherein the first delay test pattern further includes:
a launch clock pulse for generating said transition of the at least one signal input to the combinatorial circuit; and
a capture clock pulse, occurring a predetermined time after the launch clock pulse, for capturing the at least one signal value output from the combinatorial circuit to the output scan segment.

3. The method of claim 1, wherein the second delay test pattern further includes a hold clock pulse for generating said transition of the at least one signal input to the combinatorial circuit and capturing the at least one signal value output from the combinatorial circuit to the output scan segment.

4. The method of claim 1, wherein the first delay test pattern and the second delay test pattern both also include:
at least one first shift pulse for loading at least part of the input test pattern into the input scan segment; and
at least one second shift pulse for reading the at least one signal value captured by the output scan segment.

5. The method of claim 1, wherein:
the large-scale integrated circuit further includes a pre-stage combinatorial circuit that outputs at least one signal to the input scan segment of scan flip-flops;
at least one of the scan flip-flops forms a pre-stage scan segment for launching at least one signal into the pre-stage combinatorial circuit; and
the input test pattern further includes at least one signal value placed in the pre-stage scan segment to propagate through the pre-stage combinatorial circuit to the input scan segment.

6. The method of claim 5, wherein the first delay test pattern further includes:
at least one first shift pulse for loading a first part of the input test pattern into the pre-stage scan segment and a second part of the input test pattern into the input scan segment;
a launch clock pulse for generating said transition of the at least one signal input to the combinatorial circuit by causing the input scan segment to latch the at least one signal output from the pre-stage combinatorial circuit after the first part of the input test pattern has propagated through the pre-stage combinatorial circuit;
a capture clock pulse, occurring a predetermined time after the launch clock pulse, for capturing the at least one signal value output from the combinatorial circuit into the output scan segment; and
at least one second shift pulse for reading the at least one signal value captured by the output scan segment.

7. The method of claim 5, wherein the second delay test pattern further includes:
at least one first shift pulse for loading a first part of the input test pattern into the pre-stage scan segment and a second part of the input test pattern into the input scan segment;
a hold clock pulse for generating said transition of the at least one signal input to the combinatorial circuit by causing the input scan segment to latch the at least one signal output from the pre-stage combinatorial circuit after the first part of the input test pattern has propagated through the pre-stage combinatorial circuit, and capturing the at least one signal value output from the combinatorial circuit to the output scan segment; and
at least one second shift pulse for reading the at least one signal value captured by the output scan segment.

8. The method of claim 1, wherein the large-scale integrated circuit further includes at least one external input terminal for input of an external signal through the input scan segment to the combinatorial circuit, and the first delay test pattern and the second test delay pattern create said transition by having the input scan segment latch the at least one external signal after latching the input test pattern.

9. The method of claim 1, wherein the scan flip-flops are interconnected into a single scan chain.

10. The method of claim 1, wherein the scan flip-flops are interconnected to form a plurality of scan chains, the input scan segment and the output scan segment being disposed in separate scan chains.

11. The method of claim 1, wherein the first delay test is conducted before the second delay test.

12. The method of claim 11, wherein the second delay test is conducted only if the large-scale integrated circuit passes the first delay test.

13. The method of claim 1, wherein the second delay test is conducted before the first delay test.

14. The method of claim 13, wherein the first delay test is conducted only if the large-scale integrated circuit passes the second delay test.
